(19) United States
(12) Patent Application Publication
(10) Pub. No.: US 2009/0121739 A1
(43) Pub. Date: May 14, 2009

(54) AC DETECTING APPARATUS FOR DETECTING OPERATING STATES OF AC POWER SUPPLY

(75) Inventor: HENG-CHEN KUO, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/967,044

(22) Filed: Dec. 29, 2007

(30) Foreign Application Priority Data
Nov. 13, 2007 (CN) 200710202504.1

(51) Int. Cl. G01R 19/155

(52) U.S. Cl. 324/771; 324/133

(57) ABSTRACT

An exemplary AC detecting apparatus for detecting operating states of an AC power supply includes a detecting circuit connected to an AC power supply, the detecting circuit comprising a photocoupler having a luminous element with the anode connected to a live line of the AC power supply and the cathode connected to a neutral line of the AC power supply, and an optical receiving block with the cathode grounded and the anode connected to a first power source via a resistor; and a processor comprising an interrupt terminal connected to the anode of the optical receiving block, and an output terminal, wherein the detecting circuit detects the AC power supply to send a trigger signal to the processor for triggering a detecting program preinstalled in the processor to real-time analyze the operating states of the AC power supply, and outputs a result of the program via the output terminal.

### BACKGROUND

1. Field of the Invention

The present invention relates to alternating current (AC) detecting apparatuses, and particularly to an AC detecting apparatus for detecting operating states of an AC power supply.

2. Description of Related Art

Modern companies are relying more and more on their computer networks for their day to day operations. It is therefore, essential for the computer networks to be operational all of the time. A power failure can quickly bring down a computer network since all the network hubs and gateways require power to function. To ensure reliable network operation, most companies use uninterruptible power supplies (UPS) to protect their computer network equipment from failing during a power failure. UPS is a device that provides battery backup when the electrical power fails or drops to an unacceptable voltage level. However, some times the AC power supply does not fail but suffers frequency departure, the UPS should be started when this occurs to protect computer networks as well.

What is needed, therefore, is an AC detecting apparatus for detecting operating states of an AC power supply to determine whether the UPS should be started.

### SUMMARY

In one aspect, the present invention relates to an AC detecting apparatus for detecting operating states of an AC power supply and comprises a detecting circuit arranged to be connected to an AC power supply, the detecting circuit comprising a photocoupler having a luminous element with the anode connected to a live line of the AC power supply and the cathode connected to a neutral line of the AC power supply, and an optical receiving block with the cathode grounded and the anode connected to a first power source via a first resistor; and a processor comprising an interrupt terminal connected to the anode of the optical receiving block of the photocoupler, and an output, wherein the detecting circuit detects the AC power supply and sends a trigger signal to the processor for triggering a detecting program preinstalled in the processor to analyze the operating states of the AC power supply in real-time, the processor outputs a result of the program via the output terminal.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is a diagram of an AC detecting apparatus for detecting operating states of an AC power supply with an embodiment of the present invention having an AC power supply, a detecting circuit, and a frequency generator;

FIG. 2 is a circuit diagram of an embodiment of the detecting circuit of FIG. 1;

FIG. 3 is a circuit diagram of another embodiment of the detecting circuit of FIG. 1; and

FIG. 4 is a graph comparing cycles of the AC power supply, the detecting circuit, and the frequency generator of FIG. 1.

### DETAILED DESCRIPTION

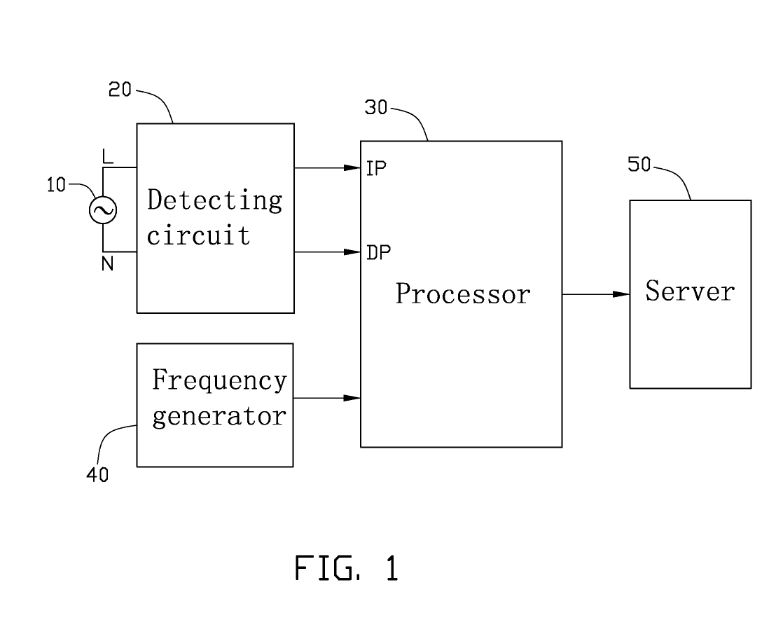

Referring to FIG. 1, an AC detecting apparatus for detecting operating states of an AC power supply in accordance with an embodiment of the present invention includes an AC power supply 10, a detecting circuit 20, a processor 30, a frequency generator 40, and a server 50. The detecting circuit 20 is connected to the AC power supply 10 for detecting operating states of the AC power supply 10 and connected to the processor to send a trigger signal to the processor 30 for triggering a detecting program preinstalled in the processor 30 to analyze the operating state of the AC power supply 10 in real-time. The processor 30 is connected to the server 50 to send a result of the program to the server 50. The frequency generator 40 is connected to the processor 30 to provide pulses to the processor 30.

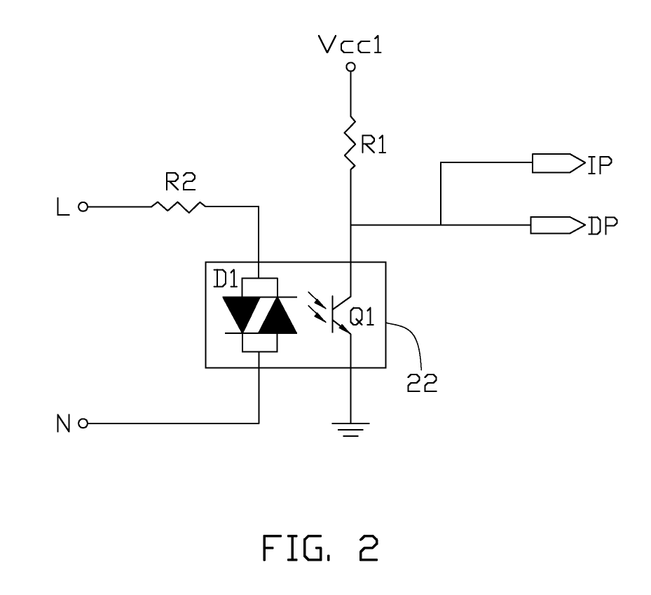

Referring to FIG. 2, in a first embodiment of the invention, the detecting circuit 20 includes a first power supply Vcc1, a first resistor R1, and a photocoupler 22 having a luminous element D1 such as a bidirectional light emitting diode and an optical receiving block Q1 such as a photosensitive transistor. A live wire L of the AC power supply 10 is connected to an anode of the luminous element D1 via a second resistor R2. A neutral line L of the AC power supply 10 is connected to a cathode of the luminous element D1. A cathode of the optical receiving block Q1 is grounded, and an anode of the optical receiving block Q1 is connected to an interrupt terminal IP and an enable terminal D1 of the processor 30, and connected to the first power supply Vcc1 via the first resistor R1.

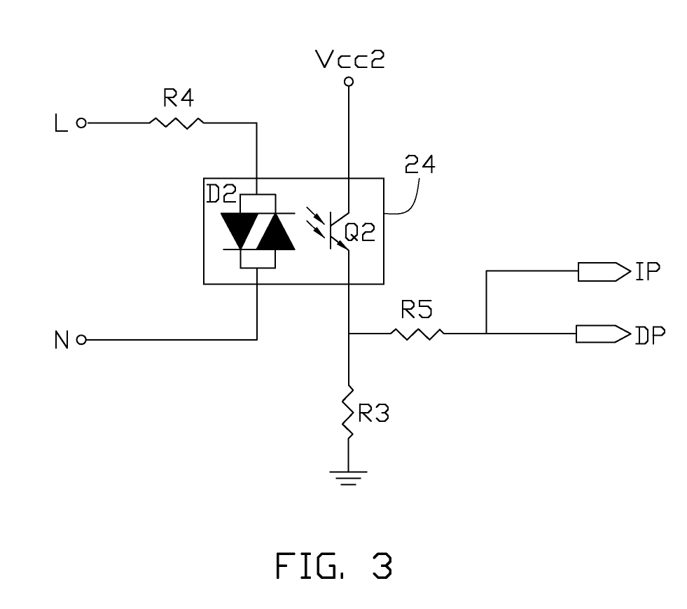

Referring to FIG. 3, in a second embodiment of the invention, the detecting circuit 20 includes a second power supply Vcc2, a third resistor R3, and a photocoupler 24 having a luminous element D2 and an optical receiving block Q2. The live wire L of the AC power supply 10 is connected to an anode of the luminous element D2 via a fourth resistor R4. The neutral line L of the AC power supply 10 is connected to a cathode of the luminous element D2. A cathode of the optical receiving block Q2 is grounded via a third resistor R3, and an anode of the optical receiving block Q2 is connected to the interrupt terminal IP and the enable terminal DP of the processor 30 via a fifth resistor R5, and connected to the second power supply Vcc2.

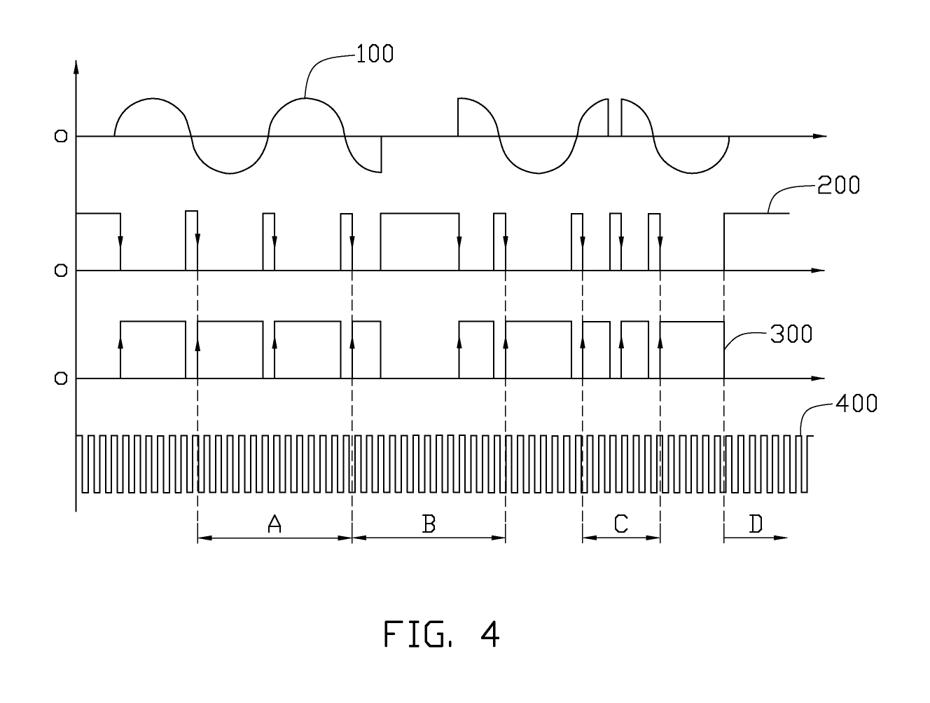

Referring to FIG. 4, curve 100 is a frequency waveform of the AC power supply 10. Curve 400 is a frequency waveform of the frequency generator 40. Curves 200 and 300 are waveforms of the trigger signals generated by the first and second embodiments of the detecting circuit 20.

In the first embodiment of the invention, the trigger signal generated by the detecting circuit 20 has three trailing edges in each cycle. The first trailing edge in a cycle will trigger the processor 30 via the interrupt terminal IP and enable the processor 30 via the enable terminal DP which enables at a high level. Therefore, the processor 30 counts a number X of the pulses received from the frequency generator 40 between the first and the second trailing edges (part A as shown in FIG. 4). The second trailing edge in the cycle will trigger the processor 30 via the interrupt terminal IP for counting a number Y of the pulses received from the frequency generator 40 between the second and the third trailing edges. The processor 30 compares a difference between X and Y with a reference value N which is found by using the following equation: N=((1/F1)*E)/(1/F2), wherein F1 is a frequency of the AC power supply 10, E is a error rate of the AC power supply 10, and F2 is the frequency of the pulses generated by the frequency generator 40. Therefore, if the difference between X and Y is zero, the AC power supply 10 is normal; if the difference between X and Y is smaller than N, the AC power supply 10 is frequency departure; if the difference between X and Y is greater than N, transient interruption has occurred (part B and C as shown in FIG. 4); if the X or Y is zero, the AC power supply has failed (part D as shown in FIG. 4)(because when the AC power supply is fail, the processor can not be triggered to count).

In the second embodiment of the invention, the trigger signal generated by the detecting circuit 20 has three rising edges in each cycles because the interrupt terminal IP is connected between the photocoupler 24 and ground, and the enable terminal DP is set to be enabled at a high level. Therefore, operators may set the processor 30 to be triggered by a low level voltage according to the detecting circuit 20 to have a same function as in the first embodiment.

The detecting circuit 20 detects the AC power supply and generates the trigger signal to the processor 30 for triggering the detecting program preinstalled in the processor 30 to real-time analyze the operating states of the AC power supply 10. The processor 30 transmits the result of the detecting program to the server 50 to report that the AC power supply is normal, frequency departure, or failed.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An AC detecting apparatus for detecting operating states of an AC power supply comprising:
a detecting circuit arranged to be connected to an AC power supply, the detecting circuit comprising a photocoupler having a luminous element with the anode connected to a live line of the AC power supply and the cathode connected to a neutral line of the AC power supply, and an optical receiving block with the cathode grounded and the anode connected to a first power source via a first resistor; and
a processor comprising an interrupt terminal connected to the anode of the optical receiving block of the photocoupler, and an output terminal,
wherein, the detecting circuit detects the AC power supply to send a trigger signal to the processor for triggering a detecting program preinstalled in the processor to real-time analyze the operating states of the AC power supply, the processor outputs a result of the program via the output terminal.

2. The AC detecting apparatus as claimed in claim 1, wherein the detecting program comprises steps of:
providing a frequency generator to provide pulses to the processor;
counting a first number of the pulses received from the frequency generator in half of a cycle of the AC power supply;
counting a second number of the pulses received from the frequency generator in another half of the cycle of the power supply; and
comparing a difference between the first and second numbers with a reference value to distinguish the operating state of the AC power supply.

3. The AC detecting apparatus as claimed in claim 1, wherein the output terminal of the processor is connected to a server for transmitting the result of the program.

4. The AC detecting apparatus as claimed in claim 1, wherein the processor further comprises an enable terminal connected to the anode of the optical receiving block of the photocoupler, the processor is enable when the enable terminal is at a high level.

5. An AC detecting apparatus for detecting operating states of an AC power supply comprising:
a detecting circuit arranged to be connected to an AC power supply, the detecting circuit comprising a photocoupler having a luminous element with the anode connected to a live line of the AC power supply and the cathode connected to a neutral line of the AC power supply, and an optical receiving block with the cathode grounded via a second resistor and the anode connected to a second power source; and
a processor comprising an interrupt terminal connected to the cathode of the optical receiving block of the photocoupler, and an output terminal,
wherein, the detecting circuit detects the AC power supply to send a trigger signal to the processor, and trigger the detecting program preinstalled in the processor to real-time analyze the operating states of the AC power supply, the processor outputs a result of the program via the output terminal.

6. The AC detecting apparatus as claimed in claim 5, wherein the detecting program comprises steps of:
providing a frequency generator to provide pulses to the processor;
counting a first number of the pulses received from the frequency generator in half of a cycle of the AC power supply;
counting a second number of the pulses received from the frequency generator in another half of the cycle of the power supply; and
comparing a difference between the first and second numbers with a reference value to distinguish the operating state of the AC power supply.

7. The AC detecting apparatus as claimed in claim 5, wherein the output terminal of the processor is connected to a server for transmitting the result of the program.

8. The AC detecting apparatus as claimed in claim 5, wherein the processor further comprises an enable terminal connected to the cathode of the optical receiving block of the photocoupler, the processor is enable when the enable terminal is at a low level.
